(19) United States
(12) Patent Application Publication
(10) Pub. No.: US 2024/0306448 A1
(43) Pub. Date: Sep. 12, 2024

(54) Display Substrate, Manufacturing Method and Driving Method Therefor, Display Device and Vehicle Lamp

(71) Applicants: Chengdu BOE Optoelectronics Technology Co., Ltd.; BOE Technology Group Co., Ltd.

(72) Inventor: Zhenli ZHOU, Beijing (CN)

(21) Appl. No.: 18/280,679

(22) PCT Filed: Feb. 20, 2023
(86) PCT No.: PCT/CN2023/077074

§ 371 Date: Sep. 7, 2023

(30) Foreign Application Priority Data
Apr. 13, 2022 (CN) 202210388486.5

(51) Int. Cl. H10K 59/131; H10K 59/12

(52) U.S. Cl. CPC H10K 59/131; H10K 59/1201

(57) ABSTRACT

A display substrate is provided, including a base substrate; multiple light emitting elements, wherein the light emitting element includes a first electrode, a light emitting functional layer and a second electrode, the light emitting functional layer is on a side of the first electrode away from the base substrate, the second electrode is on a side of the light emitting functional layer away from the base substrate; multiple power supply signal lines, each power supply signal lines is connected with at least one light emitting element; a thickness of the power supply signal line is greater than that of the first electrode; the power supply signal line is on a side of the first electrode away from the base substrate, an orthographic projection of the power supply signal line on the base substrate is at least partially overlapped with that the first electrode on the base substrate.

### CROSS-REFERENCE TO RELATED APPLICATIONS

The present application is a U.S. National Phase Entry of International Application PCT/CN2023/077074 having an international filing date of Feb. 20, 2023 claims priority of Chinese patent application No. 202210388486.5, filed to the CNIPA on Apr. 13, 2022, and entitled “Display Substrate, Manufacturing Method and Driving Method Therefor, Display Device and Vehicle Lamp”, the contents of which should be interpreted as being incorporated herein by reference.

### TECHNICAL FIELD

The present disclosure relates to, but is not limited to, the field of display technology, and in particular to a display substrate, a method for manufacturing the display substrate, a method for driving the display substrate, a display device and a vehicle lamp.

### BACKGROUND

In an OLED (Organic Light-Emitting Diode) rigid vehicle taillight project, there are about 50% dark point defects. An analysis on the defects shows that when a thin anode layer located on a relative upper layer is connected with a power supply signal line located on a relative lower layer through a via formed in an insulation layer, breakage of lines will easily occur at a position of the via due to a small thickness of the anode layer, which leads to open circuit of OLED and dark point defects.

### SUMMARY

In a first aspect, an embodiment of the present disclosure provides a display substrate, including: a base substrate;
a plurality of light emitting elements, wherein each light emitting element includes a first electrode, a light emitting functional layer and a second electrode, the light emitting functional layer is located on a side of the first electrode away from the base substrate, the second electrode is located on a side of the light emitting functional layer away from the base substrate;
a plurality of power supply signal lines, wherein each of the power supply signal lines is connected with at least one of the light emitting elements;
wherein a thickness of the power supply signal line is greater than a thickness of the first electrode;
the power supply signal line is located on a side of the first electrode away from the base substrate, an orthographic projection of the power supply signal line on the base substrate is at least partially overlapped with an orthographic projection of the first electrode on the base substrate; and
the power supply signal line is connected with the first electrode.

In some embodiments, the plurality of power supply signal lines extend along a first direction and a second direction respectively, and are connected into a grid;
the first electrode includes a first sub-part and a second sub-part, and the first sub-part is connected with the second sub-part;
the first sub-part is in a block shape, and an orthographic projection of the first sub-part on the base substrate is located in the grid; and
the second sub-part is in a strip shape extending along the first direction and/or the second direction of the grid, and an orthographic projection of the second sub-part on the base substrate is at least partially overlapped with the orthographic projection of the power supply signal line on the base substrate.

In some embodiments, the plurality of power supply signal lines extend along a first direction and a second direction respectively, and are connected into a grid;
the first electrode includes a first sub-part, a second sub-part and a third sub-part, and the first sub-part, the second sub-part and the third sub-part are connected in sequence;
an orthographic projection of the first sub-part and an orthographic projection of the second sub-part on the base substrate are located in the grid;
the first sub-part is in a block shape, the second sub-part is in a strip shape extending along a direction parallel to the first direction and/or the second direction of the grid, and the second sub-part surrounds a periphery of the first sub-part; and
an orthographic projection of the third sub-part on the base substrate is overlapped with an orthographic projection of a power supply signal line on the base substrate, and the third sub-part is in contact with and connected to the power supply signal line.

In some embodiments, an extension length of the second sub-part along the first direction and/or the second direction is at least ¼ of a perimeter of the grid.

In some embodiments, a passivation layer is also included and located between the first electrode and the power supply signal line;
the passivation layer is provided with a plurality of first openings and a plurality of second openings;
a first opening is located in an overlapped area between the orthographic projections of the second sub-part and the power supply signal line, and the power supply signal line is in contact and connected with the second sub-part through the first opening; and
an orthographic projection of a second opening on the base substrate is overlapped with the orthographic projection of the first sub-part on the base substrate.

In some embodiments, the thickness of the power supply signal line is greater than a thickness of the passivation layer.

In some embodiments, the power supply signal lines are divided into a plurality of groups;
each group includes a plurality of the power supply signal lines, and the plurality of the power supply signal lines in each group are connected with one signal input line.

In some embodiments, a pixel define layer is also included and located on a side of the power supply signal lines away from the base substrate; and
the pixel define layer is provided with a plurality of third openings, and an orthographic projection of a third opening on the base substrate is overlapped with the orthographic projection of the first sub-part on the base substrate.

In some embodiments, the light emitting functional layers of the plurality of light emitting elements are connected together as a whole;
the second electrodes of the plurality of light emitting elements are connected together as a whole; and
the light emitting functional layer and the second electrode also extend to a side of the pixel define layer away from the base substrate.

In some embodiments, an encapsulation layer is also included and located on a side of the second electrode away from the base substrate; and
the encapsulation layer includes a first inorganic encapsulation layer, an organic encapsulation layer and a second inorganic encapsulation layer; the first inorganic encapsulation layer, the organic encapsulation layer and the second inorganic encapsulation layer are sequentially stacked in a direction away from the base substrate.

In some embodiments, the second electrode is made of an opaque and conductive material; and
the first electrode is made of a light-transmissive and conductive material.

In some embodiments, a thickness of the first electrode is ≤2000 angstroms; and
a thickness of the power supply signal line ranges from 2 to 3 m.

In some embodiments, a material of the first electrode includes indium tin oxide or indium zinc oxide; and
a material of the power supply signal lines include aluminum and titanium.

In a second aspect, an embodiment of the present disclosure further provides a display device including the display substrate described above.

In a third aspect, an embodiment of the present disclosure further provides a vehicle lamp including the display substrate described above.

In a fourth aspect, an embodiment of the present disclosure provides a method for manufacturing a display panel, including:
manufacturing a plurality of light emitting elements and a plurality of power supply signal lines on a base substrate;
manufacturing the light emitting elements includes sequentially manufacturing first electrodes, a light emitting functional layer and second electrodes on the base substrate;
wherein the power supply signal lines are manufactured after the first electrodes are manufactured; a thickness of the power supply signal line is greater than a thickness of the first electrodes; an orthographic projection of the power supply signal lines on the base substrate is at least partially overlapped with an orthographic projection of the first electrodes on the base substrate; and the power supply signal lines are connected with the first electrodes.

In some embodiments, the display substrate is the display substrate described above;
the method includes: after the first electrodes are manufactured and before the power supply signal lines are manufactured, the method further includes: manufacturing a passivation layer and patterns of a plurality of first openings and a plurality of second openings in the passivation layer;
manufacturing the first electrode includes simultaneously forming patterns of first sub-parts and second sub-parts;
an orthographic projection of the second sub-parts on the base substrate is overlapped with the an orthographic projection of the power supply signal lines on the base substrate; and
the power supply signal lines are in contact with and connected with the second sub-parts through the first openings respectively.

In some embodiments, the display substrate is the display substrate described above;

The method includes: manufacturing the first electrodes includes simultaneously forming patterns of first sub-parts, second sub-parts and third sub-parts;
an orthographic projection of the third sub-part on the base substrate is overlapped with the orthographic projection of the power supply signal lines on the base substrate, and the power supply signal lines are in contact with and connected to the third sub-parts respectively.

In a fifth aspect, an embodiment of the present disclosure further provides a method for driving a display substrate, including: a first electrode of the light emitting element receives a driving voltage signal inputted from a power supply signal line; and
the light emitting functional layer of the light emitting element emits light under action of an electric field formed between the first electrode and a second electrode of the light emitting element.

In some embodiments, the display substrate is the display substrate described above;

The method includes: simultaneously inputting driving voltage signals to a plurality of power supply signal lines through different signal input lines; or
inputting driving voltage signals to each group of the power supply signal lines through different signal input lines at different times;
wherein the driving voltage signals inputted to different signal input lines have a same or different amplitudes.

### BRIEF DESCRIPTION OF DRAWINGS

Accompanying drawings are used to provide a further understanding of technical solution of the present disclosure, and constitute a part of the specification. They are used together with embodiments of the present application to explain the technical solution of the present disclosure, and do not constitute a restriction on the technical solution of the present disclosure. The above and other features and advantages will become more apparent to those skilled in the art by describing detailed exemplary embodiments with reference to the accompanying drawings, in which:

FIG. 1 is a top view of a structure of a vehicle taillight in the disclosed art.

FIG. 2 is a sectional view of a structure taken along a section line AA′ in FIG. 1.

FIG. 3 is a schematic diagram of disconnection of an anode layer at a position of a via in FIG. 2.

FIG. 4 is a top view of a structure of a display substrate according to an embodiment of the present disclosure.

FIG. 5 is a sectional view of a structure taken along a section line BB′ in FIG. 4.

FIG. 6 is a top view of a structure of another display substrate according to an embodiment of the present disclosure.

FIG. 7 is a sectional view of a structure taken along a section line CC′ in FIG. 6.

FIG. 8 is a schematic diagram of arrangement of signal input lines in a display substrate according to an embodiment of the present disclosure.

### DETAILED DESCRIPTION

In order to enable those skilled in the art to better understand the technical solution of the embodiments of the present disclosure, a display substrate, a method for manufacturing the display substrate, a method for driving the display substrate, a display device and a vehicle lamp provided by the embodiments of the present disclosure are further described in detail with reference to the drawings and specific embodiments.

Embodiments of that present disclosure will be described more fully hereinafter with reference to the accompany drawings, but the illustrated embodiments may be embodied in different forms and should not be construed as being limited to the embodiments set forth in the present disclosure. On the contrary, these embodiments are provided for the purpose of making the present disclosure thorough and complete, and will enable those skilled in the art to fully understand the scope of the present disclosure.

Embodiments of the present disclosure are not limited to the embodiment shown in the drawings, but include modifications of configurations formed based on manufacturing processes. Therefore, regions illustrated in the drawings have schematic properties, and shapes of the regions shown in the drawings illustrate specific shapes of the regions, but are not intended to be restrictive.

Hereafter, terms “first” and “second” are only used for description and should not be construed as indicating or implying relative importance or implicitly indicating the number of indicated technical features. Therefore, features defined with “first” and “second” may explicitly or implicitly include one or more of such features. In the descriptions of the present disclosure, “a plurality of/multiple” means two or more than two, unless otherwise specified.

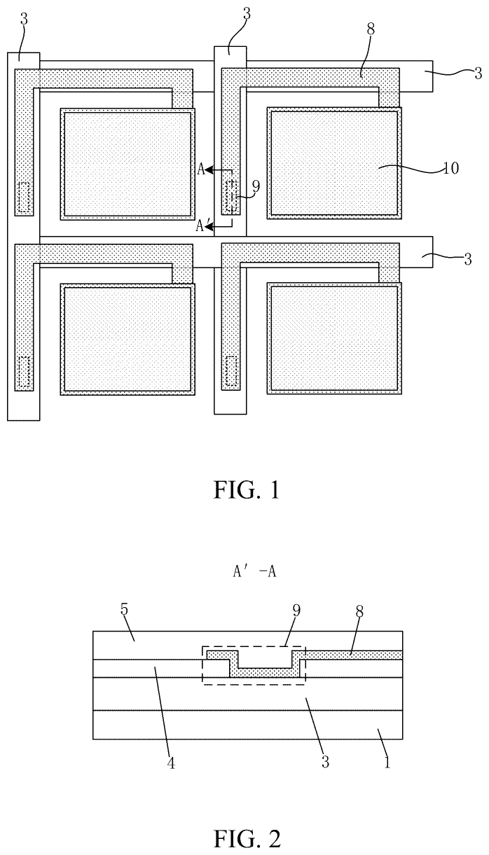

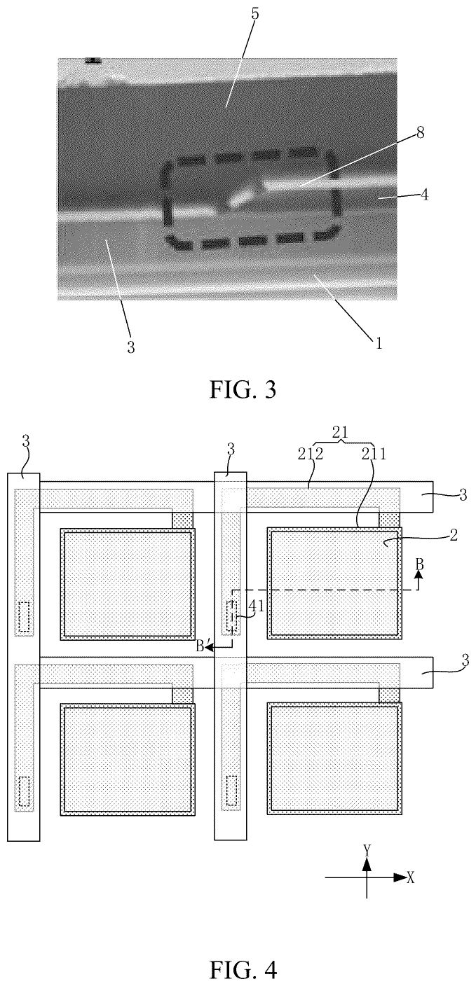

In the disclosed art, referring to FIG. 1 to FIG. 3, FIG. 1 is a top view of the structure of a vehicle taillight in the disclosed art. FIG. 2 is a sectional view of a structure taken along a section line AA′ in FIG. 1. FIG. 3 is a schematic diagram of disconnection of an anode layer at a position of a via in FIG. 2. In an OLED (Organic Light-Emitting Diode) rigid vehicle taillight project, firstly, a power supply signal line 3 is manufactured on a rigid substrate 1, then a passivation layer 4 is manufactured on the power supply signal line 3, and then an anode 8 of an OLED light emitting element 10 is manufactured on the passivation layer 4. A pixel define layer 5 is further provided on a side of the anode 8 away from the base substrate 1. An orthographic projection of the anode 8 and an orthographic projection of the power supply signal line 3 are partially overlapped on the base substrate 1, and the passivation layer 4 is provided with a via 9 in an area corresponding the overlapped area between orthographic projections of the anode 8 and the power supply signal line 3. An anode layer located on a relatively upper layer is connected with the power supply signal line 3 located on a relatively lower layer through the via 9 in the passivation layer 4, so that a power supply signal on the power supply signal line 3 is input to the anode 8 of the OLED light emitting element 10 to drive the OLED light emitting element 10 to emit light.

Since a film layer of the anode 8 is thin, when the anode layer is connected to the power supply signal line 3 through the via 9, disconnection of the anode layer will easily occur on a slope side wall of the via 9, which, referring to FIG. 3, leads to that the OLED light emitting element 10 is broken and dark points appear.

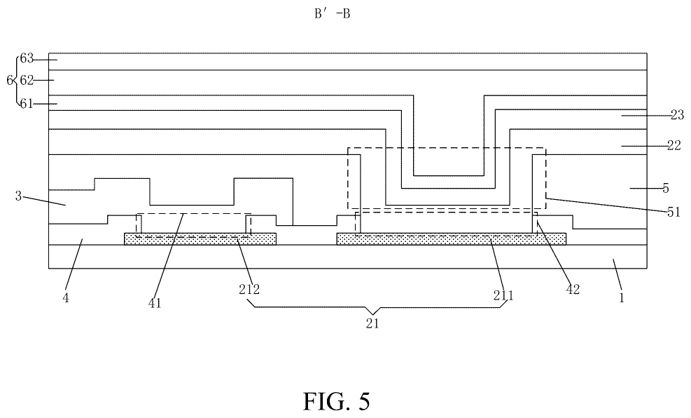

In order to solve the problem of dark point defects in vehicle taillight in the disclosed art, in the first aspect, an embodiment of the present disclosure provides a display substrate, referring to FIGS. 4 and 5, and FIG. 4 is a top view of a structure of a display substrate according to an embodiment of the present disclosure, FIG. 5 is a sectional view of a structure along a section line BB′ in FIG. 4. The display substrate includes: a base substrate 1; a plurality of light emitting elements 2, wherein a light emitting element 2 includes a first electrode 21, a light emitting functional layer 22 and a second electrode 23, the light emitting functional layer 22 is located on a side of the first electrode 21 away from the base substrate 1, the second electrode 23 is located on a side of the light emitting functional layer 22 away from the base substrate 1; a plurality of power supply signal lines 3, wherein each power supply signal line 3 is connected with at least one of the light emitting elements 2. Among them, a thickness of the power supply signal line 3 is larger than a thickness of a first electrode 21, and the power supply signal line 3 is located on a side of the first electrode 21 away from the base substrate 1.

An orthographic projection of the power supply signal line 3 on the base substrate 1 is at least partially overlapped with an orthographic projection of a first electrode 21 on the base substrate 1, and the power supply signal line 3 is connected to the first electrode 21.

The light emitting element 2 may be an OLED element i.e. an organic electroluminescent element. The light emitting functional layer 22 of the OLED element may include film layers, such as a hole transport layer, a hole injection layer, a light emitting layer, an electron injection layer, an electron transport layer and the like. The light emitting element 2 may also be an LED element i.e. a light emitting diode. The light emitting element 2 may also be a Mini LED or Micro LED element. A first voltage signal on the power supply signal line 3 is input to the first electrode 21, and the second electrode 23 is connected to another potential terminal, that is, a second voltage signal is input to the second electrode 23 through another potential terminal. The first voltage signal is not equal to the second voltage signal, and the light emitting functional layer 22 is excited to emit light under action of a current formed between the power supply signal line 3 and another potential terminal.

In this embodiment, by providing a thick power supply signal line 3 on the side of a thin first electrode 21 away from the base substrate 1, the first electrode 21 can be prevented from being broken when the first electrode 21 is connected to the power supply signal line 3, thereby avoiding the problem of dark points on the display substrate.

In some embodiments, a thickness of the first electrode 21 is less than or equal to 2000 angstroms, and a thickness of the power supply signal line 3 ranges from 2 to 3 km.

In some embodiments, the plurality of power supply signal lines 3 extend along a first direction X and a second direction Y respectively, and are connected into a grid. The first electrode 21 includes a first sub-part 211 and a second sub-part 212. The first sub-part 211 is connected to the second sub-part 212, the first sub-part 211 is in a block shape, and an orthographic projection of the first sub-part 211 on the base substrate 1 is located in the grid. The second sub-part 212 is in a strip shape extending along the first direction X and/or the second direction Y of the grid, and an orthographic projection of the second sub-part 212 on the base substrate 1 is at least partially overlapped with an orthographic projection of the power supply signal line 3 on the base substrate 1. With such arrangement, an area of a region in the grid where the light emitting element 2 is located can be increased, thereby increasing a display aperture ratio of the display substrate.

Referring to FIGS. 4 and 5, the first sub-part 211 serves as an anode of the light emitting element 2, the strip-shaped second sub-part 212 is configured to limit a current inputted to the first sub-part 211 by the power supply signal line 3. The strip-shaped second sub-part 212 may be made of indium tin oxide or indium zinc oxide material. The strip-shaped second sub-part 212 of such material has a large resistance, and can limit the current inputted to the first sub-part 211, so as to prevent short circuit between the first sub-part 211 and the second electrode 23 caused by a too large current inputted to the first sub-part 211, thereby protecting a power source providing input signals from being burned out by short circuit, and further ensuring that other light emitting elements 2 connected in parallel with each other can emit light normally.

In some embodiments, referring to FIG. 4, the orthographic projection of the second sub-part 212 on the base substrate 1 is completely overlapped with the orthographic projection of the power supply signal line 3 on the base substrate 1. With such arrangement, the area of the region in the grid where the light emitting element 2 is located can be further increased, thereby further increasing a display aperture ratio of the display substrate.

In some embodiments, the display substrate further includes a passivation layer 4 located between the first electrode 21 and the power supply signal line 3. The passivation layer 4 is provided with a plurality of first openings 41 and a plurality of second openings 42. A first opening 41 is located in an overlapped area between the orthographic projections of the second sub-part 212 and the power supply signal line 3, and the power supply signal line 3 is in contact and connected with the second sub-part 212 through the first opening 41. An orthographic projection of the second opening 42 on the base substrate 1 is overlapped with the orthographic projection of the first sub-part 211 on the base substrate 1. With such arrangement, since the thickness of the power supply signal line 3 is larger than the thickness of the first electrode 21, the power supply signal line 3 will not be easily broken when being connected to the first electrode 21 through the first opening 41, thereby avoiding dark point defects in the light emitting element 2.

In some embodiments, the orthographic projection of the second opening 42 on the base substrate 1 coincides with the orthographic projection of the first sub-part 211 on the base substrate 1. Thus, the aperture ratio of the display substrate is further improved.

In some embodiments, the second opening 42 enables the light emitting functional layer 22 and the second electrode 23 to be stacked on the first electrode 21 in sequence, and achieves direct contact between the light emitting functional layer 22 and the first electrode 21, thereby implementing a function of normal light emitting of the light emitting element 2 under current drive.

In some embodiments, the thickness of the power supply signal line 3 is greater than a thickness of the passivation layer 4. With such arrangement, the first opening 41 can be filled flat with the power supply signal line 3, thereby further ensuring that the connection between the power supply signal line 3 and the first electrode 21 will not be broken, and preventing the light emitting element 2 from having dark points.

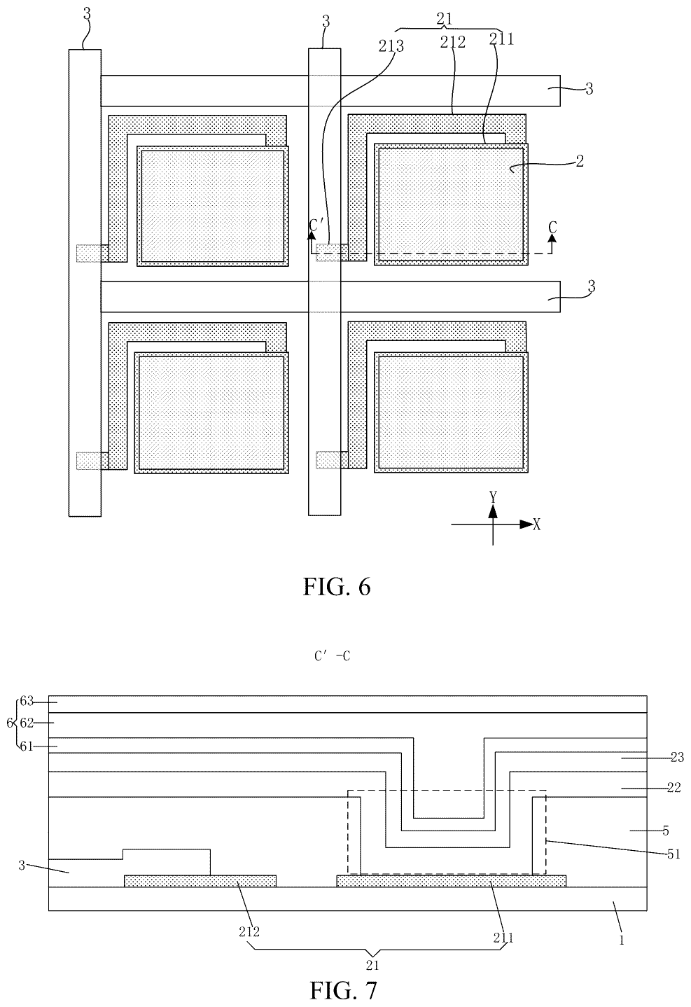

In some embodiments, with reference to FIGS. 6 and 7, FIG. 6 is a top view of a structure of another display substrate according to an embodiment of the present disclosure. FIG. 7 is a sectional view of a structure taken along a section line CC′ in FIG. 6. A plurality of power supply signal lines 3 extend along a first direction X and a second direction Y, respectively, and are connected into a grid. The first electrode 21 includes a first sub-part 211, a second sub-part 212, and a third sub-part 213. The first sub-part 211, the second sub-part 212 and the third sub-part 213 are connected in sequence. An orthographic projection of the first sub-part 211 and the second sub-part 212 on the base substrate 1 is located in the grid. The first sub-part 211 is in a block shape, the second sub-part 212 is in a strip shape extending along a direction parallel to the first direction X and/or the second direction Y of the grid, and the second sub-part 212 surrounds a periphery of the first sub-part 211. An orthographic projection of the third sub-part 213 on the base substrate 1 is overlapped with an orthographic projection of the power supply signal line 3 and the third sub-part 213 is in contact with and connected to the power supply signal line 3.

In FIGS. 6 and 7, the first sub-part 211 serves as an anode of the light emitting element 2. The strip-shaped second sub-part 212 is configured to limit a current inputted to the first sub-part 211 by the power supply signal line 3. The strip-shaped second sub-part 212 may be made of indium tin oxide or indium zinc oxide material. The strip-shaped second sub-part 212 of such material has a large resistance, and can limit the current inputted to the first sub-part 211, so as to prevent short circuit between the first sub-part 211 and the second electrode 23 caused by too large current inputted to the first sub-part 211, thereby protecting a power source providing input signals from being burned out by short circuit, and further ensuring that other light emitting elements 2 connected in parallel with each other can emit light normally.

In FIGS. 6 and 7, no passivation layer is provided in the display substrate, that is, the first sub-part 211 and the second sub-part 212 are on the same layer as the power supply signal line 3 on the base substrate 1. The third sub-part 213 is directly lapped with and connected to the power supply signal line 3.

In some embodiments, an extension length of the second sub-part 212 along the first direction X and/or the second direction Y is at least ¼ of a perimeter of a grid. In some embodiments, an extension length of the second sub-part 212 is ½ of a perimeter of the grid. A length of the strip-shaped second sub-part 212 is specifically designed according to its requirement for adjusting a magnitude of the current driving the light emitting element 2 to emit light.

In some embodiments, the display substrate further includes a pixel define layer 5 located on a side of the power supply signal line 3 away from the base substrate 1. The pixel define layer 5 is provided with a plurality of third openings 51, and an orthographic projection of a third opening 51 on the base substrate 1 is overlapped with the orthographic projection of the first sub-part 211 on the base substrate 1. The third opening 51 is configured to define a formation position of the light emitting element 2, i.e. the third opening 51 is configured to accommodate the light emitting element 2.

In some embodiments, the orthographic projection of the third opening 51 on the base substrate 1 coincides with the orthographic projection of the first sub-part 211 on the base substrate 1. Therefore, the aperture ratio of the display substrate can be further improved. In some embodiments, the light emitting functional layers 22 of the plurality of light emitting elements 2 are connected together as a whole, the second electrodes 23 of the plurality of light emitting elements 2 are connected together as a whole, and the light emitting functional layers 22 and the second electrodes 23 also extend to a side of the pixel define layer 5 away from the base substrate 1.

In this embodiment, the light emitting functional layer 22 emits light of one color, such as white light or red light, thereby achieving the function of the display substrate applied to the vehicle lamp.

In this embodiment, the light emitting element 2 does not need to be provided with a drive circuit can be lit directly through a first voltage signal input on the power supply signal line 3.

In some embodiments, the light emitting functional layers of the plurality of light emitting elements may also be separately arranged, and the second electrodes of the plurality of light emitting elements are connected together as a whole. Thus, the light emitting functional layers of different light emitting elements can emit light of different colors, thereby achieving a color display function of the display substrate. In some embodiments, when the display substrate is used for implementing a display function, a drive circuit for driving the light emitting elements to emit light may be provided to implement independent lighting control of different light emitting elements.

In some embodiments, the display substrate further includes an encapsulation layer 6 located on a side of the second electrode 23 away from the base substrate 1. The encapsulation layer 6 includes a first inorganic encapsulation layer 61, an organic encapsulation layer 62, and a second inorganic encapsulation layer 63. The first inorganic encapsulation layer 61, the organic encapsulation layer 62, and the second inorganic encapsulation layer 63 are sequentially stacked along a direction away from the base substrate 1. The encapsulation layer 6 can prevent external water and oxygen from intruding into the light emitting element 2, thereby protecting the light emitting elements from being damaged.

In some embodiments, the second electrode 23 is made of an opaque and conductive material. The first electrode 21 is made of a light-transmissive and conductive material. That is, the display substrate can implement bottom-emission light emitting, and when a bottom-emission display substrate is applied to the vehicle lamp, color cast of large angle of view when the vehicle lamp emits light can be reduced, and a light emitting effect of the vehicle lamp can be improved.

In some embodiments, the second electrode may also be made of a light transmissive and conductive material, and first electrode is made of an opaque and conductive material. In this way, the top-emission light emitting or display of the display substrate is implemented.

In some embodiments, the material of the first electrode 21 includes indium tin oxide (ITO) or indium zinc oxide (IZO), and the material of the power supply signal line 3 includes aluminum and titanium, such as a laminate of titanium/aluminum/titanium.

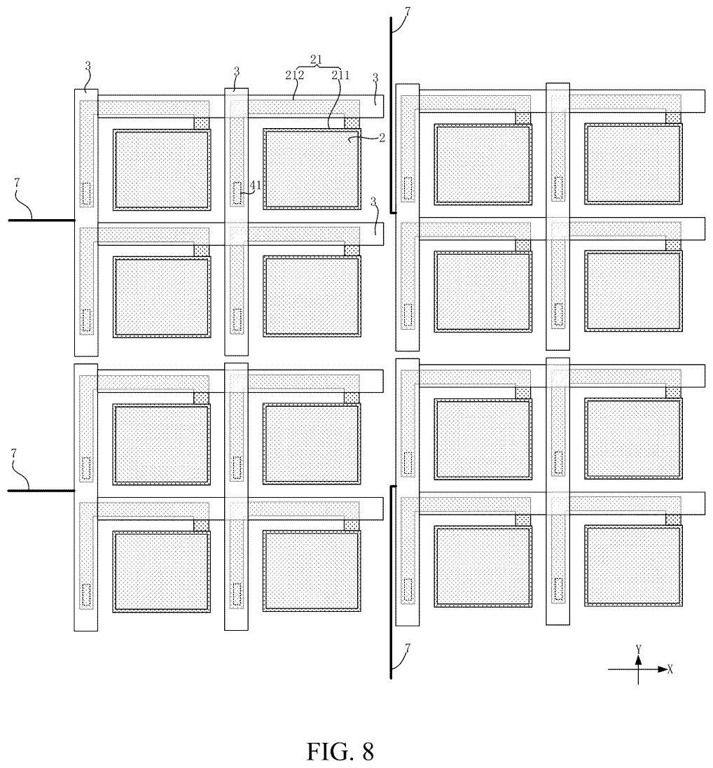

In some embodiments, referring to FIG. 8, which is a schematic diagram of the arrangement of signal input lines in a display substrate according to an embodiment of the present disclosure. Power supply signal lines 3 are divided into a plurality of groups, each group includes a plurality of power supply signal lines 3, and the plurality of power supply signal lines 3 in each group are connected to one signal input line 7. By providing the signal input lines 7, the light emitting elements 2 connected to each group of power supply signal lines 3 can be controlled for independent lighting, thereby achieving some special lighting effects of the display substrate, such as time-sharing driving of the light emitting elements 2 connected to each group of power supply signal lines 3, or driving the light emitting elements 2 connected to each group of power supply signal lines 3 to emit light with different brightness.

In some embodiments, the signal input lines 7 are arranged in a same layer and are made of a same material as the power supply signal lines 3.

In an embodiment of the present disclosure, by disposing a thick power supply signal line 3 on a side of a thin first electrode 21 away from the base substrate 1, the first electrode 21 can be prevented from being broken when the first electrode 21 is connected to the power supply signal line 3, thereby avoiding the problem of dark points on the display substrate.

In a second aspect, based on the display substrate with the structure provided by the embodiment of the disclosure, an embodiment of the disclosure further provides a method for manufacturing the display substrate described above, which includes the following steps: manufacturing a plurality of light emitting elements and a plurality of power supply signal lines on a base substrate, wherein manufacturing the light emitting element includes sequentially manufacturing first electrodes, a light emitting functional layer and second electrodes on a base substrate; wherein the power supply signal line are manufactured after the first electrodes are manufactured, a thickness of the power supply signal lines is greater than a thickness of the first electrodes, an orthographic projection of the power supply signal lines on the base substrate is at least partially overlapped with an orthographic projection of the first electrodes on the base substrate, and the power supply signal lines is connected with the first electrodes respectively.

In some embodiments, referring to FIG. 5, the method for manufacturing the display substrate includes: manufacturing a passivation layer 4 and patterns of a plurality of first openings 41 and a plurality of second openings 42 in the passivation layer 4 after the manufacturing of the first electrodes 21 is completed and before the manufacturing of the power supply signal lines 3; manufacturing the first electrodes 21 includes simultaneously forming patterns of the first sub-parts 211 and the second sub-parts 212; an orthographic projection of the second sub-parts 212 on the base substrate 1 is overlapped with the orthographic projection of the power supply signal lines 3 on the base substrate 1; the power supply signal lines 3 are in contact with and connected to the second sub-parts 212 through the first openings 41.

In some embodiments, the passivation layer 4 and the patterns of the first openings 41 and the second openings 42 therein are manufactured by a patterning process (including film deposition, exposure, development, etching, etc.) or an evaporation process (such as an FMM evaporation process, i.e. a metal mask evaporation with the passivation layer 4 and the patterns of the first openings 41 and the second openings 42 therein). The patterns of the first electrodes 21 and the patterns of the power supply signal lines 3 are also manufactured by a patterning process or an evaporation process respectively. The first electrodes 21 and the power supply signal lines 3 are successively manufactured by two processes, respectively.

In some embodiments, referring to FIG. 7, the method for manufacturing a display substrate includes: manufacturing the first electrodes 21 includes simultaneously forming patterns of the first sub-parts 211, the second sub-parts 212, and the third sub-parts 213; an orthographic projection of the third sub-parts 213 on the base substrate 1 is overlapped with the orthographic projection of the power supply signal lines 3 on the base substrate 1, and the power supply signal lines 3 are in contact with and connected to the third sub-parts 213.

The patterns of the first electrodes 21 and the patterns of the power supply signal lines 3 are also manufactured by a patterning process or an evaporation process respectively. The first electrodes 21 and the power supply signal lines 3 are successively manufactured by two processes, respectively.

In a third aspect, an embodiment of the present disclosure further provides a method for driving the display substrate described above, which includes the following steps: a first electrode of a light emitting element receives a driving voltage signal input from a power supply signal line; the light emitting functional layer of the light emitting element emits light under action of an electric field formed between the first electrode and a second electrode of the light emitting element.

In some embodiments, the method for driving the display substrate includes: simultaneously inputting a driving voltage signal to a plurality of groups of power supply signal lines through different signal input lines, thereby achieving the simultaneous emitting of all the light emitting elements in the display substrate, and achieving the function of the display substrate applied to the vehicle lamp.

In some embodiments, the method for driving the display substrate includes: inputting driving voltage signals to each group of power supply signal lines through different signal input lines at different times, thereby achieving the time-sharing drive of the light emitting elements connected to each power supply signal line, and achieving some dynamic light emitting of the display substrate applied to vehicle lamp. Such as arrow indicator lights or some flashing lights applied to vehicles.

In some embodiments, the method for driving the display substrate includes: the driving voltage signals input on different signal input lines are the same or different in magnitude. In this way, light emitting of different brightness by the light emitting elements connected to each group of power supply signal lines is implemented, so that the display substrate can be applied to displaying some still pictures with different brightness partitions.

In some embodiments, the method for driving the display substrate may also be a combination of the above driving methods.

In a fourth aspect, an embodiment of the present disclosure further provides a display device including the display substrate described above.

By adopting the display substrate in the embodiment described, the problem of poor display dark points in the display device is avoided.

The display device may be any product or component with a display function, such as an OLED panel, an OLED television, a mobile phone, a tablet computer, a laptop computer, a monitor, a digital photo frame, and a navigator.

In a fifth aspect, an embodiment of the present disclosure further provides a vehicle lamp, which includes the display substrate described above.

By adopting the display substrate in the above embodiment, the problem of poor dark points in the vehicle lamp is avoided.

The vehicle lamp may be: lamps of various automobiles, lamps of high-speed trains, lighting lamps on airplanes, etc.

It is to be understood that the above implementation modes are only exemplary implementation used for illustrating principles of the present disclosure, however the present disclosure is not limited thereto. For those of ordinary skills in the art, various modifications and improvements may be made without departing from the spirit and substance of the present disclosure, and these modifications and improvements are also considered to be within the scope of the present disclosure.

1. A display substrate, comprising: a base substrate;
a plurality of light emitting elements, wherein each light emitting element comprises a first electrode, a light emitting functional layer and a second electrode, the light emitting functional layer is located on a side of the first electrode away from the base substrate, the second electrode is located on a side of the light emitting functional layer away from the base substrate;
a plurality of power supply signal lines, wherein each of the power supply signal lines is connected with at least one of the light emitting elements;
wherein a thickness of the power supply signal line is greater than a thickness of the first electrode;
the power supply signal line is located on a side of the first electrode away from the base substrate, an orthographic projection of the power supply signal line on the base substrate is at least partially overlapped with an orthographic projection of the first electrode on the base substrate; and
the power supply signal line is connected with the first electrode.

2. The display substrate according to claim 1, wherein the plurality of power supply signal lines extend along a first direction and a second direction respectively, and are connected into a grid;
the first electrode comprises a first sub-part and a second sub-part, and the first sub-part is connected with the second sub-part;
the first sub-part is in a block shape, and an orthographic projection of the first sub-part on the base substrate is located in the grid; and
the second sub-part is in a strip shape extending along the first direction and/or the second direction of the grid, and an orthographic projection of the second sub-part on the base substrate is at least partially overlapped with an orthographic projection of a power supply signal line on the base substrate.

3. The display substrate according to claim 1, wherein the plurality of power supply signal lines extend along a first direction and a second direction respectively, and are connected into a grid;
the first electrode comprises a first sub-part, a second sub-part and a third sub-part, and the first sub-part, the second sub-part and the third sub-part are connected in sequence;
an orthographic projection of the first sub-part and an orthographic projection of the second sub-part on the base substrate are located in the grid;
the first sub-part is in a block shape, the second sub-part is in a strip shape extending along a direction parallel to the first direction and/or the second direction of the grid, and the second sub-part surrounds a periphery of the first sub-part; and
an orthographic projection of the third sub-part on the base substrate is overlapped with an orthographic projection of a power supply signal line on the base substrate, and the third sub-part is in contact with and connected to the power supply signal line.

4. The display substrate according to claim 2-or-, wherein an extension length of the second sub-part along the first direction and/or the second direction is at least ¼ of a perimeter of the grid.

5. The display substrate according to claim 2, further comprising a passivation layer located between the first electrode and the power supply signal line;
the passivation layer is provided with a plurality of first openings and a plurality of second openings;
a first opening is located in an overlapped area between the orthographic projections of the second sub-part and the power supply signal line, and the power supply signal line is in contact and connected with the second sub-part through the first opening; and
an orthographic projection of a second opening on the base substrate is overlapped with the orthographic projection of the first sub-part on the base substrate.

6. The display substrate according to claim 5, wherein a thickness of the power supply signal line is greater than a thickness of the passivation layer.

7. The display substrate according to claim 1, wherein the power supply signal lines are divided into a plurality of groups;
each group comprises a plurality of the power supply signal lines, and the plurality of the power supply signal lines in each group are connected with one signal input line.

8. The display substrate according to claim 2, further comprising a pixel define layer located on a side of the power supply signal lines away from the base substrate; and
the pixel define layer is provided with a plurality of third openings, and an orthographic projection of a third opening on the base substrate is overlapped with the orthographic projection of the first sub-part on the base substrate.

9. The display substrate according to claim 8, wherein the light emitting functional layer of the plurality of light emitting elements are connected together as a whole;
the second electrodes of the plurality of light emitting elements are connected together as a whole; and
the light emitting functional layer and the second electrode also extend to a side of the pixel define layer away from the base substrate.

10. The display substrate according to claim 9, further comprising an encapsulation layer located on a side of the second electrode away from the base substrate; and
the encapsulation layer comprises a first inorganic encapsulation layer, an organic encapsulation layer and a second inorganic encapsulation layer; the first inorganic encapsulation layer, the organic encapsulation layer and the second inorganic encapsulation layer are sequentially stacked in a direction away from the base substrate.

11. The display substrate according to claim 1, wherein the second electrode is made of an opaque and conductive material; and
the first electrode is made of a light-transmissive and conductive material.

12. The display substrate according to claim 1, wherein a thickness of the first electrode ≤2000 angstroms; and
a thickness of the power supply signal lines ranges from 2 to 3 m.

13. The display substrate according to claim 12, wherein a material of the first electrode comprises indium tin oxide or indium zinc oxide; and
a material of the power supply signal lines comprise aluminum and titanium.

14. A display device, comprising the display substrate according to claim 1.

15. A vehicle lamp, comprising the display substrate according to claim 1.

16. A method for manufacturing a display substrate, comprising:
manufacturing a plurality of light emitting elements and a plurality of power supply signal lines on a base substrate;
manufacturing the light emitting elements comprises sequentially manufacturing first electrodes, a light emitting functional layer and second electrodes on the base substrate;
wherein the power supply signal lines are manufactured after the first electrodes are manufactured; a thickness of the power supply signal lines is greater than a thickness of the first electrodes; an orthographic projection of the power supply signal lines on the base substrate is at least partially overlapped with an orthographic projection of the first electrodes on the base substrate; and the power supply signal lines are connected with the first electrodes.

17. The method for manufacturing the display substrate according to claim 16, wherein the display substrate further comprises a passivation layer located between the first electrodes and the power supply signal lines:
the passivation layer is provided with a plurality of first openings and a plurality of second openings;
a first opening is located in an overlapped area between orthographic projections of a second sub-part and a power supply signal line, and the power supply signal line is in contact and connected with the second sub-part through the first opening:
an orthographic projection of a second opening on the base substrate is overlapped with the orthographic projection of the first sub-part on the base substrate;
the method comprises: after the first electrode are manufactured and before the power supply signal lines are manufactured, the method further comprises: manufacturing a passivation layer and patterns of a plurality of first openings and a plurality of second openings in the passivation layer;
manufacturing the first electrodes comprises simultaneously forming patterns of first sub-parts and second sub-parts;
an orthographic projection of the second sub-parts on the base substrate is overlapped with the an orthographic projection of the power supply signal lines on the base substrate; and
the power supply signal lines are in contact with and connected with the second sub-parts through the first openings respectively.

18. The method for manufacturing the display substrate according to claim 16, wherein the plurality of power supply signal lines extend along a first direction and a second direction respectively, and are connected into a grid;
each first electrode comprises a first sub-part, a second sub-part and a third sub-part, and the first sub-part, the second sub-part and the third sub-part are connected in sequence;
an orthographic projection of the first sub-part and an orthographic projection of the second sub-part on the base substrate are located in the grid;
the first sub-part is in a block shape, the second sub-part is in a strip shape extending along a direction parallel to the first direction and/or the second direction of the grid, and the second sub-part surrounds a periphery of the first sub-part;
an orthographic projection of the third sub-part on the base substrate is overlapped with an orthographic projection of a power supply signal line on the base substrate, and the third sub-part is in contact with and connected to the power supply signal line;
the method comprises: manufacturing the first electrodes comprises simultaneously forming patterns of first sub-parts, second sub-parts and third sub-parts;
an orthographic projection of the third sub-part on the base substrate is overlapped with the orthographic projection of the power supply signal lines on the base substrate, and the power supply signal lines are in contact with and connected to the third sub-parts respectively.

19. A method for driving a display substrate, comprising: a first electrode of a light emitting element receives a driving voltage signal inputted from a power supply signal line; and
the light emitting functional layer of the light emitting element emits light under action of an electric field formed between the first electrode and a second electrode of the light emitting element.

20. The method for driving the display substrate according to claim 19, wherein the power supply signal lines are divided into a plurality of groups;
each group comprises a plurality of the power supply signal lines, and the plurality of the power supply signal lines in each group are connected with one signal input line;
the method comprises: simultaneously inputting driving voltage signals to a plurality of power supply signal lines through different signal input lines; or
inputting driving voltage signals to each group of the power supply signal lines through different signal input lines at different times;
wherein the driving voltage signals inputted to different signal input lines have a same or different amplitudes.
